(19) United States
(12) Patent Application Publication
(10) Pub. No.: US 2020/0135596 A1
(43) Pub. Date: Apr. 30, 2020

(54) COVER GLASS AND AIRTIGHT PACKAGE USING SAME

(71) Applicant: Nippon Electric Glass Co., Ltd., Shiga (JP)

(72) Inventor: Masayuki HIROSE, Shiga (JP)

(21) Appl. No.: 16/605,629

(22) PCT Filed: Mar. 15, 2018
(86) PCT No.: PCT/JP2018/010197

§ 371 Date: Oct. 16, 2019

(30) Foreign Application Priority Data
Apr. 17, 2017 (JP) 2017-081147

(51) Int. Cl. H01L 23/04; C03C 17/04; C03C 27/10; H01L 23/10

(52) U.S. Cl. CPC H01L 23/04; H01L 23/10; C03C 27/10; C03C 17/04

(57) ABSTRACT

A cover glass of the present invention includes a sealing material layer on one surface, wherein the sealing material layer has a gap formed therein.

### TECHNICAL FIELD

The present invention relates to a cover glass and a hermetic package using the cover glass, and more specifically, to a cover glass including a sealing material layer in a predetermined shape, and a hermetic package using the cover glass.

### BACKGROUND ART

A hermetic package generally includes a package base, a cover glass having light transmissivity, and an internal device to be housed inside thereof.

There is a risk in that the internal device to be mounted in the hermetic package, such as a microelectromechanical system (MEMS) device, deteriorates owing to moisture penetrating from a surrounding environment. An organic resin-based adhesive having low-temperature curability has hitherto been used for integrating the package base and the cover glass with each other. However, the organic resin-based adhesive cannot completely block moisture or a gas, and hence there is a risk in that the internal device deteriorates with time.

Meanwhile, when composite powder including glass powder and refractory filler powder is used as a sealing material, the sealed sites are less liable to deteriorate owing to moisture of a surrounding environment, and the hermetic reliability of the hermetic package is easily ensured.

However, the glass powder has a higher softening temperature than the organic resin-based adhesive, and hence there is a risk in that the internal device is thermally degraded at the time of sealing. Under such circumstances, laser sealing has attracted attention in recent years.

In the laser sealing, in general, a laser at a wavelength in a near-infrared region (hereinafter referred to as near-infrared laser) is radiated to a sealing material layer, and then the sealing material layer softens and deforms to hermetically integrate the cover glass and the package base with each other. In the laser sealing, only a portion to be sealed can be locally heated, and hence the package base and the cover glass can be hermetically integrated with each other without thermal degradation of the internal device.

### CITATION LIST

Patent Literature 1: JP 2014-12634 A

### SUMMARY OF INVENTION

### Technical Problem

In order to improve laser sealing efficiency, the sealing material layer has a higher ability to absorb near-infrared light than the cover glass. Moreover, while the sealing material layer is directly heated with a near-infrared laser at the time of laser sealing, the cover glass is not directly heated with the near-infrared laser because the cover glass hardly absorbs near-infrared light. That is, on a surface of the cover glass, a region in which the sealing material layer is formed is locally heated at the time of laser sealing, but a region in which the sealing material layer is not formed is not locally heated.

Based on the presence or absence of the local heating, a difference in expansion/shrinkage occurs between the region of the cover glass in which the sealing material layer is formed and the region of the cover glass in which the sealing material layer is not formed, and thermal strain is generated in the surface of the cover glass. The thermal strain often causes breakage of the cover glass, which causes a significant problem in ensuring hermetic reliability.

In dealing with the above-mentioned problem, when the width of the sealing material layer is increased, the thermal strain can be alleviated. However, when the width of the sealing material layer is too large, a difference in temperature between a center portion and an end edge portion of the sealing material layer in a width direction is increased. As a result, there is a risk in that the hermetic reliability may be reduced owing to uneven distribution of the thermal strain.

The present invention has been made in view of the above-mentioned circumstances, and a technical object of the present invention is to provide a cover glass capable of reducing thermal strain in the cover glass at the time of laser sealing and a hermetic package using the cover glass.

### Solution to Problem

The inventor of the present invention has repetitively performed various experiments, and as a result, has found that the above-mentioned technical object can be achieved by arranging a gap in a sealing material layer. Thus, the finding is proposed as the present invention. That is, according to one embodiment of the present invention, there is provided a cover glass, comprising a sealing material layer on one surface, wherein the sealing material layer has a gap formed therein. Herein, the “gap” refers to a portion in which the sealing material layer is not formed, the portion being arranged in the sealing material layer without communicating with an outside in a planar view.

In the cover glass according to the embodiment of the present invention, the sealing material layer has the gap formed therein. With this, at the time of laser sealing, a temperature gradient between a center portion and an end edge portion of the sealing material layer in a width direction is alleviated, and hence a difference in expansion/shrinkage is less liable to occur in the surface of the cover glass, and thermal strain is less liable to be generated in the surface of the cover glass. As a result, the cover glass is less liable to be broken.

In addition, in the cover glass according to the embodiment of the present invention, it is preferred that a width of the gap of the sealing material layer be from 2% to 60% of an average width of the sealing material layer. Herein, the “width of the gap” refers to the length dimension of the gap in the width direction of the sealing material layer. The “average width of the sealing material layer” refers to the average width of the sealing material layer on the assumption that the sealing material layer has no gap.

In addition, in the cover glass according to the embodiment of the present invention, it is preferred that the gap be formed along a center line of the sealing material layer.

In addition, in the cover glass according to the embodiment of the present invention, it is preferred that the sealing material layer be formed in a frame shape along a peripheral end edge of the cover glass.

In addition, in the cover glass according to the embodiment of the present invention, it is preferred that the sealing material layer have an average thickness of less than 8.0 μm. With this, a stress remaining in a hermetic package after the laser sealing is reduced, and hence the hermetic reliability of the hermetic package can be improved.

FIG. 1 (a) is a schematic top view for illustrating an example of the cover glass according to the embodiment of the present invention. As apparent from FIG. 1 (a), a sealing material layer 15 is formed on one surface of a cover glass 11 in a frame shape along a peripheral end edge of the cover glass 11. In addition, a gap G in a linear shape is formed over the entire periphery of the sealing material layer 15 along a center line of the sealing material layer 15 in a width direction. The width of the gap G is about 10% of the average width of the sealing material layer 15 (in the figure, the width of the gap G is illustrated in an exaggerated manner). FIG. 1(b) is a schematic top view for illustrating an example of the cover glass according to the embodiment of the present invention. As apparent from FIG. 1(b), the sealing material layer 15 is formed on one surface of the cover glass 11 in a frame shape along a peripheral end edge of the cover glass 11. In addition, gaps G in a true circle shape are continuously formed in the sealing material layer 15 at a constant interval along a center line of the sealing material layer 15 in a width direction. The width of each of the gaps G is about 15% of the average width of the sealing material layer 15 (in the figure, the width of each of the gaps G is illustrated in an exaggerated manner).

According to one embodiment of the present invention, there is provided a hermetic package, comprising a package base and a cover glass, wherein the hermetic package further comprises a sealing material layer arranged between the package base and the cover glass, and wherein the sealing material layer has a gap formed therein.

In addition, in the hermetic package according to the embodiment of the present invention, it is preferred that a width of the gap of the sealing material layer be from 2% to 60% of an average width of the sealing material layer.

In addition, in the hermetic package according to the embodiment of the present invention, it is preferred that the package base comprise a base part and a frame part formed on the base part, the package base have an internal device housed within the frame part, and the sealing material layer be arranged between a top of the frame part of the package base and the cover glass. With this, the internal device is easily housed in a space within the hermetic package.

In addition, in the hermetic package according to the embodiment of the present invention, it is preferred that the package base comprise any one of glass, glass ceramic, aluminum nitride, and aluminum oxide, or a composite material thereof.

The present invention is described below with reference to the drawings. FIG. 2 is a schematic sectional view for illustrating an embodiment of the present invention. As can be seen from FIG. 2, a hermetic package 1 comprises a package base 10 and the cover glass 11. In addition, the package base 10 comprises a base part 12 and a frame part 13 in a frame shape along a peripheral end edge of the base part 12. Moreover, an internal device 14 is housed within the frame part 13 of the package base 10. Electrical wiring (not shown) configured to electrically connect the internal device 14 to an outside is formed in the package base 10.

A gap is formed over the entire periphery of the sealing material layer 15 along a center line of the sealing material layer in a width direction. The width of the gap is about 8% of the average width of the sealing material layer. Further, the average thickness of the sealing material layer 15 is less than 8.0 μm. Moreover, the sealing material layer 15 is arranged between a top of the frame part 13 of the package base 10 and a surface of the cover glass 11 on an internal device 14 side over the entire periphery of the top of the frame part 13. In addition, the sealing material layer 15 comprises bismuth-based glass and refractory filler powder, and is substantially free of a laser absorber. Moreover, the width of the sealing material layer 15 is smaller than the width of the top of the frame part 13 of the package base 10, and further, the sealing material layer 15 is distant from an end edge of the cover glass 11.

In addition, the above-mentioned hermetic package 1 may be produced as described below. First, the cover glass 11 on which the sealing material layer 15 has been formed in advance is placed on the package base 10 so that the sealing material layer 15 and the top of the frame part 13 are brought into contact with each other. Subsequently, laser light L output from a laser irradiation apparatus is radiated along the sealing material layer 15 from a cover glass 11 side. With this, the sealing material layer 15 softens and flows to react with a surface layer on the top of the frame part 13 of the package base 10, to thereby hermetically integrate the package base 10 and the cover glass 11 with each other. Thus, a hermetic structure of the hermetic package 1 is formed.

### BRIEF DESCRIPTION OF DRAWINGS

FIG. 1 are each a schematic top view for illustrating an example of a cover glass of the present invention.

FIG. 2 is a schematic sectional view for illustrating an embodiment of the present invention.

FIG. 3 is a schematic view for illustrating a softening point of composite powder measured with a macro-type DTA apparatus.

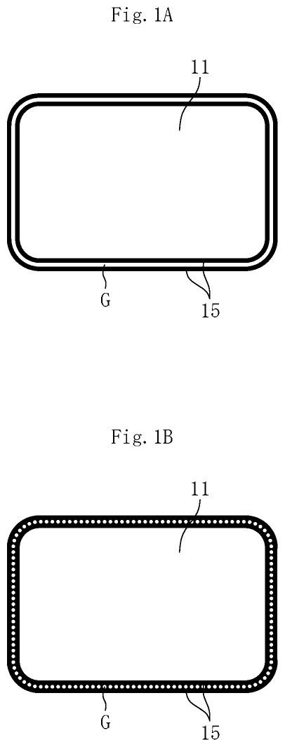

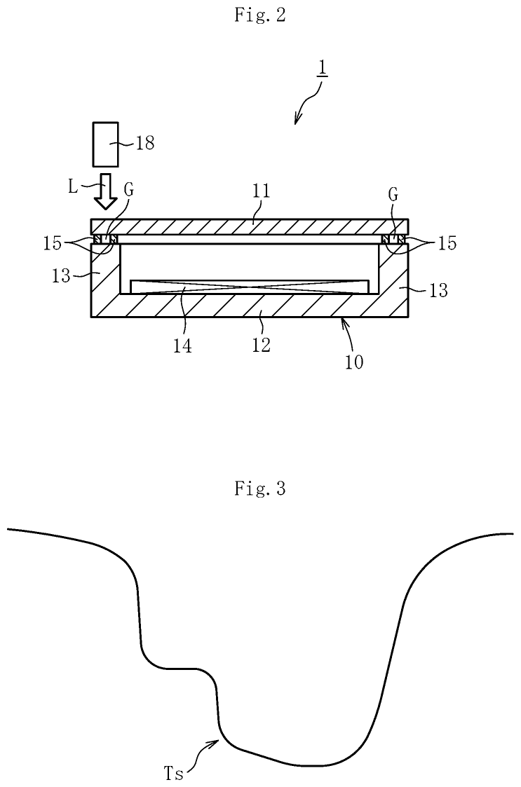

### DESCRIPTION OF EMBODIMENTS

A cover glass of the present invention comprises a sealing material layer on one surface. The sealing material layer has a function of softening and deforming at the time of laser sealing to form a reaction layer in a surface layer of a package base, to thereby hermetically integrate the package base and the cover glass with each other.

A gap is formed in the sealing material layer. The width of the gap is preferably from 2% to 60%, from 3% to 40%, or from 4% to 30%, particularly preferably from 5% to 20% of the average width of the sealing material layer. When the width of the gap is too small with respect to the average width of the sealing material layer, a difference in temperature between a center region and an end edge portion of the sealing material layer in a width direction is increased. As a result, there is a risk in that hermetic reliability may be reduced owing to uneven distribution of thermal strain. Meanwhile, when the width of the gap is too large with respect to the average width of the sealing material layer, there is a risk in that the hermetic reliability is reduced owing to reductions in laser sealing strength and accuracy of the laser sealing.

The average width of the gap is preferably from 10 μm to 800 μm, more preferably from 20 μm to 300 μm, particularly preferably from 30 μm to 200 μm. When the average width of the gap is too small, the difference in temperature between the center region and the end edge portion of the sealing material layer in the width direction is increased. As a result, there is a risk in that the hermetic reliability may be reduced owing to uneven distribution of thermal strain. Meanwhile, when the average width of the gap is too large, there is a risk in that the hermetic reliability is reduced owing to reductions in laser sealing strength and accuracy of the laser sealing.

The shape of the gap is not particularly limited, but from the viewpoint of reducing the difference in temperature between the center region and the end edge portion of the sealing material layer in the width direction, it is preferred that a gap in a linear shape be formed over the entire periphery of the sealing material layer along the center line of the sealing material layer in the width direction. It is also preferred that gaps in a true circle shape be formed continuously in the sealing material layer at a constant interval along the center line of the sealing material layer in the width direction. It is particularly preferred that the gap in a linear shape be formed over the entire periphery of the sealing material layer along the center line of the sealing material layer in the width direction.

The average width of the sealing material layer is preferably from 100 μm to 3,000 μm, more preferably from 300 μm to 2,000 μm, particularly preferably from 500 μm to 1,500 μm. When the average width of the sealing material layer is too small, there is a risk in that the hermetic reliability is reduced owing to reductions in laser sealing strength and accuracy of the laser sealing. Meanwhile, when the average width of the sealing material layer is too large, the difference in temperature between the center region and the end edge portion of the sealing material layer in the width direction is increased. As a result, there is a risk in that the hermetic reliability may be reduced owing to uneven distribution of thermal strain.

The sealing material layer is preferably formed of a sintered body of composite powder containing at least glass powder and refractory filler powder. With this, the surface smoothness of the sealing material layer can be improved. As a result, thermal strain in the cover glass is reduced at the time of laser sealing, and the hermetic reliability of a hermetic package can be improved. The glass powder is a component which softens and deforms during the laser sealing, to thereby hermetically integrate the package base and the cover glass with each other. The refractory filler powder is a component which acts as a framework material, and increases the mechanical strength of the sealing material layer while reducing the thermal expansion coefficient of the sealing material layer. The sealing material layer may comprise a laser absorber in order to improve light absorption characteristics in addition to the glass powder and the refractory filler powder.

Various materials may be used as the composite powder. Of those, composite powder containing bismuth-based glass powder and refractory filler powder is preferably used from the viewpoint of increasing laser sealing strength. As the composite powder, it is preferred to use composite powder containing 55 vol % to 95 vol % of bismuth-based glass powder and 5 vol % to 45 vol % of refractory filler powder. It is more preferred to use composite powder containing 60 vol % to 85 vol % of bismuth-based glass powder and 15 vol % to 40 vol % of refractory filler powder. It is particularly preferred to use composite powder containing 60 vol % to 80 vol % of bismuth-based glass powder and 20 vol % to 40 vol % of refractory filler powder. When the refractory filler powder is added, the thermal expansion coefficient of the sealing material layer easily matches the thermal expansion coefficients of the cover glass and the package base. As a result, a situation in which an improper stress remains in the sealed sites after the laser sealing is easily prevented. Meanwhile, when the content of the refractory filler powder is too large, the content of the bismuth-based glass powder is relatively reduced. Thus, the surface smoothness of the sealing material layer is reduced, and the accuracy of the laser sealing is liable to be reduced.

The softening point of the composite powder is preferably 510° C. or less or 480° C. or less, particularly preferably 450° C. or less. When the softening point of the composite powder is too high, it becomes difficult to increase the surface smoothness of the sealing material layer. The lower limit of the softening point of the composite powder is not particularly set, but in consideration of the thermal stability of the glass powder, the softening point of the composite powder is preferably 350° C. or more. Herein, the “softening point” refers to the fourth inflection point measured with a macro-type DTA apparatus, and corresponds to Ts in FIG. 3.

The bismuth-based glass preferably comprises as a glass composition, in terms of mol %, 28% to 60% of Bi₂O₃, 15% to 37% of B₂O₃, 0% to 30% of ZnO, and 15% to 40% of CuO+MnO. The reasons why the content range of each component is limited as described above are described below. In the description of the glass composition range, the expression “%” means “mol %”.

Bi₂O₃ is a main component for reducing a softening point. The content of Bi₂O₃ is preferably from 28% to 60% or from 33% to 55%, particularly preferably from 35% to 45%. When the content of Bi₂O₃ is too small, the softening point becomes too high, and softening flowability is liable to be reduced. Meanwhile, when the content of Bi₂O₃ is too large, the glass is liable to devitrify at the time of laser sealing, and owing to the devitrification, the softening flowability is liable to be reduced.

B₂O₃ is an essential component as a glass-forming component. The content of B₂O₃ is preferably from 15% to 37% or from 19% to 33%, particularly preferably from 22% to 30%. When the content of B₂O₃ is too small, a glass network is hardly formed, and hence the glass is liable to devitrify at the time of laser sealing. Meanwhile, when the content of B₂O₃ is too large, the glass has increased viscosity, and hence the softening flowability is liable to be reduced.

ZnO is a component which improves devitrification resistance. The content of ZnO is preferably from 0% to 30%, from 3% to 25%, or from 5% to 22%, particularly preferably from 5% to 20%. When the content of ZnO is too large, the glass composition loses its component balance, and hence the devitrification resistance is liable to be reduced contrarily.

CuO and MnO are each a component which significantly increases a laser absorption ability. The total content of CuO and MnO is preferably from 15% to 40% or from 20% to 35%, particularly preferably from 25% to 30%. When the total content of CuO and MnO is too small, the laser absorption ability is liable to be reduced. Meanwhile, when the total content of CuO and MnO is too large, the softening point is excessively increased, and the glass hardly softens and flows even through irradiation with laser light. In addition, the glass becomes thermally unstable, and is liable to devitrify at the time of laser sealing. The content of CuO is preferably from 8% to 30%, particularly preferably from 13% to 25%. The content of MnO is preferably from 0% to 25% or from 3% to 25%, particularly preferably from 5% to 15%.

In addition to the above-mentioned components, for example, the following components may be added.

SiO₂ is a component which improves water resistance. The content of SiO₂ is preferably from 0% to 5%, from 0% to 3%, or from 0% to 2%, particularly preferably from 0% to 1%. When the content of SiO₂ is too large, there is a risk in that the softening point is improperly increased. In addition, the glass is liable to devitrify at the time of laser sealing.

Al₂O₃ is a component which improves the water resistance. The content of Al₂O₃ is preferably from 0% to 10% or from 0.1% to 5%, particularly preferably from 0.5% to 3%. When the content of Al₂O₃ is too large, there is a risk in that the softening point is improperly increased.

Li₂O, Na₂O, and K₂O are each a component which reduces the devitrification resistance. Therefore, the content of each of Li₂O, Na₂O, and K₂O is preferably from 0% to 5% or from 0% to 3%, particularly preferably from 0% to less than 1%.

MgO, CaO, SrO, and BaO are each a component which improves the devitrification resistance, but are each a component which increases the softening point. Therefore, the content of each of MgO, CaO, SrO, and BaO is preferably from 0% to 20% or from 0% to 10%, particularly preferably from 0% to 5%.

Fe₂O₃ is a component which improves the devitrification resistance and the laser absorption ability. The content of Fe₂O₃ is preferably from 0% to 10% or from 0.1% to 5%, particularly preferably from 0.4% to 2%. When the content of Fe₂O₃ is too large, the glass composition loses its component balance, and hence the devitrification resistance is liable to be reduced contrarily.

Sb₂O₃ is a component which improves the devitrification resistance. The content of Sb₂O₃ is preferably from 0% to 5%, particularly preferably from 0% to 2%. When the content of Sb₂O₃ is too large, the glass composition loses its component balance, and hence the devitrification resistance is liable to be reduced contrarily.

The average particle diameter D₅₀ of the glass powder is preferably less than 15 μm or from 0.5 μm to 10 μm, particularly preferably from 1 μm to 5 μm. As the average particle diameter D₅₀ of the glass powder becomes smaller, the softening point of the glass powder is reduced more. Herein, the “average particle diameter D₅₀” refers to a value measured by laser diffractometry on a volume basis.

The refractory filler powder is preferably one kind or two or more kinds selected from cordierite, zircon, tin oxide, niobium oxide, zirconium phosphate-based ceramic, willemite, β-eucryptite, and β-quartz solid solution, particularly preferably β-eucryptite or cordierite. Those refractory filler powders each have a low thermal expansion coefficient and a high mechanical strength, and besides are each well compatible with the bismuth-based glass.

The average particle diameter D₅₀ of the refractory filler powder is preferably less than 2 μm, particularly preferably 0.1 μm or more and less than 1.5 μm. When the average particle diameter D₅₀ of the refractory filler powder is too large, the surface smoothness of the sealing material layer is liable to be reduced. Besides, the average thickness of the sealing material layer is liable to be increased, with the result that the accuracy of the laser sealing is liable to be reduced.

The 99% particle diameter D₉₉ of the refractory filler powder is preferably less than 5 μm or 4 μm or less, particularly preferably 0.3 μm or more and 3 μm or less. When the 99% particle diameter D₉₉ of the refractory filler powder is too large, the surface smoothness of the sealing material layer is liable to be reduced. Besides, the average thickness of the sealing material layer is liable to be increased, with the result that the accuracy of the laser sealing is liable to be reduced. Herein, the “99% particle diameter D₉₉” refers to a value measured by laser diffractometry on a volume basis.

The sealing material layer may further comprise a laser absorber in order to improve light absorption characteristics. However, the laser absorber has an action of accelerating the devitrification of the bismuth-based glass, and hence, the content of the laser absorber in the sealing material layer is preferably 10 vol % or less, 5 vol % or less, 1 vol % or less, or 0.5 vol % or less. It is particularly preferred that the sealing material layer be substantially free of the laser absorber. When the bismuth-based glass has satisfactory devitrification resistance, the laser absorber may be introduced at 1 vol % or more, particularly 3 vol % or more in order to improve the laser absorption ability. As the laser absorber, for example, a Cu-based oxide, an Fe-based oxide, a Cr-based oxide, a Mn-based oxide, or a spinel-type composite oxide thereof may be used.

The thermal expansion coefficient of the sealing material layer is preferably from 55×10⁻⁷/° C. to 100×10⁻⁷/° C. or from 60×10⁻⁷/° C. to 82×10⁻⁷/° C., particularly preferably from 65×10⁻⁷/° C. to 76×10⁻⁷/° C. With this, the thermal expansion coefficient of the sealing material layer matches the thermal expansion coefficients of the cover glass and the package base, and a stress remaining in the sealed sites is reduced. The “thermal expansion coefficient” refers to a value measured with a push-rod type thermal expansion coefficient measurement (TMA) apparatus in a temperature range of from 30° C. to 300° C.

The average thickness of the sealing material layer is preferably less than 8.0 μm, particularly preferably 1.0 μm or more and less than 6.0 μm. As the average thickness of the sealing material layer is reduced more, a stress remaining in the sealed sites after the laser sealing can be reduced more when the thermal expansion coefficient of the sealing material layer and the thermal expansion coefficient of the cover glass do not match each other. In addition, also the accuracy of the laser sealing can be improved more. As a method of controlling the average thickness of the sealing material layer as described above, the following methods are given: a method involving thinly applying a composite powder paste; and a method involving subjecting the surface of the sealing material layer to polishing treatment.

The monochromatic light absorption rate of the sealing material layer at a wavelength of 808 nm is preferably 60% or more, particularly preferably 70% or more. When the light absorption rate is low, the sealing material layer does not soften and deform unless a laser output at the time of laser sealing is increased. As a result, there is a risk in that improper thermal strain is generated in the cover glass. There is also a risk in that the internal device is thermally damaged. The “monochromatic light absorption rate at a wavelength of 808 nm” as used herein refers to a value obtained by measuring a reflectance and a transmittance of the sealing material layer in a thickness direction thereof with a spectrophotometer, and subtracting the total value thereof from 100%.

The surface roughness Ra of the sealing material layer is preferably less than 0.5 μm or 0.2 μm or less, particularly preferably from 0.01 μm to 0.15 μm. In addition, the surface roughness RMS of the sealing material layer is preferably less than 1.0 μm or 0.5 μm or less, particularly preferably from 0.05 μm to 0.3 μm. With this, the adhesiveness between the package base and the sealing material layer is increased, and the accuracy of the laser sealing is improved. Herein, the “surface roughness Ra” and the “surface roughness RMS” may be measured with, for example, a contact-type or non-contact-type laser film thickness meter or surface roughness meter. As a method of controlling the surface roughnesses Ra and RMS of the sealing material layer as described above, the following methods are given: a method involving subjecting the surface of the sealing material layer to polishing treatment; and a method involving reducing the particle size of refractory filler powder.

The sealing material layer may be formed by various methods. Of those, the sealing material layer is preferably formed by a method involving applying and sintering a composite powder paste. Moreover, the application of the composite powder paste is preferably performed with a coating machine, such as a dispenser or a screen printing machine. With this, the dimensional accuracy of the sealing material layer can be improved. In this case, the composite powder paste is a mixture of the composite powder and a vehicle. In addition, the vehicle generally contains a solvent and a resin. The resin is added for the purpose of adjusting the viscosity of the paste. In addition, a surfactant, a thickener, or the like may also be added thereto as required.

The composite powder paste is generally produced by kneading the composite powder and the vehicle with a triple roller or the like. The vehicle generally contains a resin and a solvent. As the resin to be used in the vehicle, there may be used an acrylic acid ester (acrylic resin), ethylcellulose, a polyethylene glycol derivative, nitrocellulose, polymethylstyrene, polyethylene carbonate, polypropylene carbonate, a methacrylic acid ester, and the like. As the solvent to be used in the vehicle, there may be used N,N′-dimethyl formamide (DMF), α-terpineol, a higher alcohol, γ-butyrolactone (γ-BL), tetralin, butylcarbitol acetate, ethyl acetate, isoamyl acetate, diethylene glycol monoethyl ether, diethylene glycol monoethyl ether acetate, benzyl alcohol, toluene, 3-methoxy-3-methylbutanol, triethylene glycol monomethyl ether, triethylene glycol dimethyl ether, dipropylene glycol monomethyl ether, dipropylene glycol monobutyl ether, tripropylene glycol monomethyl ether, tripropylene glycol monobutyl ether, propylene carbonate, dimethyl sulfoxide (DMSO), N-methyl-2-pyrrolidone, and the like.

The composite powder paste may be applied onto the package base, particularly onto the top of the frame part of the package base, but is preferably applied in a frame shape along the peripheral end edge of the cover glass. With this, the sealing material layer does not need to be seized to the package base, and thermal degradation of the internal device, such as a MEMS device, can be suppressed.

Various glasses may be used for the cover glass. For example, alkali-free glass, alkali borosilicate glass, or soda lime glass may be used. The cover glass may be laminated glass obtained by bonding a plurality of glass sheets.

A functional film may be formed on a surface of the cover glass on an internal device side, or on a surface of the cover glass on an outside. An antireflection film is particularly preferred as the functional film. With this, light reflected on the surface of the cover glass can be reduced.

The thickness of the cover glass is preferably 0.1 mm or more, or from 0.15 mm to 2.0 mm, particularly preferably from 0.2 mm to 1.0 mm. When the thickness of the cover glass is small, the strength of the hermetic package is liable to be reduced. Meanwhile, when the thickness of the cover glass is large, it becomes difficult to achieve thinning of the hermetic package.

A difference in thermal expansion coefficient between the cover glass and the sealing material layer is preferably less than 50×10⁻⁷/° C. or less than 40×10⁻⁷/° C., particularly preferably 30×10⁻⁷/° C. or less. When the difference in thermal expansion coefficient is too large, a stress remaining in the sealed sites is improperly increased, and the hermetic reliability of the hermetic package is liable to be reduced.

The sealing material layer is preferably formed along the end edge of the cover glass so as to be distant from the end edge of the cover glass by 50 μm or more, 60 μm or more, or from 70 μm to 1, 500 μm, particularly from 80 μm to 800 μm. When a distance between the end edge of the cover glass and the sealing material layer is too short, a difference in surface temperature between the surface of the cover glass on the internal device side and the surface of the cover glass on the outside is increased in an end edge region of the glass cover at the time of laser sealing, and the cover glass is liable to be broken.

A hermetic package of the present invention comprises a package base and a cover glass, wherein the hermetic package further comprises a sealing material layer arranged between the package base and the cover glass, and wherein the sealing material layer has a gap formed therein. The technical features of the hermetic package of the present invention have already been partially described in the description section of the cover glass of the present invention. For convenience, the detailed description of the overlapping portions is omitted.

In the hermetic package of the present invention, the package base preferably comprises a base part and a frame part formed on the base part. With this, an internal device is easily housed within the frame part of the package base. The frame part of the package base is preferably formed in a frame shape on a periphery of the package base. With this, an effective area for functioning as a device can be enlarged. In addition, the internal device is easily housed in a space within the hermetic package. Besides, for example, joining of wiring is easily performed.

On the top of the frame part, a surface of a region in which the sealing material layer is to be formed preferably has a surface roughness Ra of less than 1.0 μm. When the surface roughness Ra on the surface is increased, the accuracy of laser sealing is liable to be reduced.

The width of the top of the frame part is preferably from 100 μm to 3,000 μm or from 200 μm to 1,500 μm, particularly preferably from 300 μm to 900 μm. When the width of the top of the frame part is too small, it becomes difficult to align the sealing material layer and the top of the frame part. Meanwhile, when the width of the top of the frame part is too large, the effective area for functioning as a device is reduced.

The sealing material layer is preferably formed so that its contact position with the frame part is distant from the inner peripheral end edge of the top of the frame part and distant from the outer peripheral end edge of the top of the frame part. The sealing material layer is more preferably formed at a position distant from the inner peripheral end edge of the top of the frame part by 50 μm or more, 60 μm or more, or from 70 μm to 2,000 μm, particularly from 80 μm to 1,000 μm. When a distance between the inner peripheral end edge of the top of the frame part and the sealing material layer is too short, it becomes difficult to release heat generated through local heating during the laser sealing, and hence the cover glass is liable to be broken in the course of cooling. Meanwhile, when the distance between the inner peripheral end edge of the top of the frame part and the sealing material layer is too long, it becomes difficult to achieve downsizing of the hermetic package. In addition, the sealing material layer is preferably formed at a position distant from the outer peripheral end edge of the top of the frame part by 50 μm or more, 60 μm or more, or from 70 μm to 2,000 μm, particularly from 80 μm to 1,000 μm. When a distance between the outer peripheral end edge of the top of the frame part and the sealing material layer is too short, it becomes difficult to release heat generated through local heating during the laser sealing, and hence the cover glass is liable to be broken in the course of cooling. Meanwhile, when the distance between the outer peripheral end edge of the top of the frame part and the sealing material layer is too long, it becomes difficult to achieve downsizing of the hermetic package.

The thickness of the base part of the package base is preferably from 0.1 mm to 4.5 mm, particularly preferably from 0.2 mm to 3.5 mm. With this, thinning of the hermetic package can be achieved.

The height of the frame part of the package base, that is, a height obtained by subtracting the thickness of the base part from the package base is preferably from 100 μm to 4,000 μm, particularly preferably from 200 μm to 3,000 μm. With this, thinning of the hermetic package is easily achieved while the internal device is properly housed therein.

The package base is preferably formed of any one of glass, glass ceramic, aluminum nitride, and aluminum oxide, or a composite material thereof (e.g., a composite material in which aluminum nitride and glass ceramic are integrated with each other). Glass ceramic easily forms a reaction layer with the sealing material layer, and hence high sealing strength can be ensured through the laser sealing. Further, glass ceramic facilitates formation of a thermal via, and hence a situation in which the temperature of the hermetic package is excessively increased can be properly prevented. Aluminum nitride and aluminum oxide each have a satisfactory heat dissipating property, and hence a situation in which the temperature of the hermetic package is excessively increased can be properly prevented.

It is preferred that glass ceramic, aluminum nitride, and aluminum oxide each have dispersed therein a black pigment (be each sintered under a state in which a black pigment is dispersed therein). With this, the package base can absorb laser light having transmitted through the sealing material layer. As a result, a portion of the package base to be brought into contact with the sealing material layer is heated during the laser sealing, and hence the formation of the reaction layer can be promoted at an interface between the sealing material layer and the package base.

As a method of producing the hermetic package of the present invention, it is preferred to radiate laser light to the sealing material layer from a cover glass side to soften and deform the sealing material layer, to thereby hermetically integrate the package base and the cover glass with each other to obtain a hermetic package. In this case, the cover glass may be arranged below the package base, but from the viewpoint of the efficiency of the laser sealing, the cover glass is preferably arranged above the package base.

Various lasers may be used as the laser. In particular, a near-infrared semiconductor laser is preferred because the laser is easy to handle.

An atmosphere for performing the laser sealing is not particularly limited. An air atmosphere or an inert atmosphere, such as a nitrogen atmosphere, may be adopted.

At the time of laser sealing, when the cover glass is preheated at a temperature equal to or higher than 100° C. and equal to or lower than the temperature limit of the internal device, the breakage of the cover glass due to thermal shock at the time of laser sealing is easily suppressed. In addition, when an annealing laser is radiated from the cover glass side immediately after the laser sealing, the breakage of the cover glass due to thermal shock or a residual stress is more easily suppressed.

The laser sealing is preferably performed under a state in which the cover glass is pressed. With this, the softening and deforming of the sealing material layer can be promoted at the time of laser sealing.

### EXAMPLES

Now, the present invention is described by way of Examples. The following Examples are merely illustrative. The present invention is by no means limited to the following Examples.

Examples (Sample Nos. 1 to 5) of the present invention are shown in Table 1. Comparative Examples (Sample Nos. 6 to 10) are shown in Table 2.

TABLE 1

| | No. 1 | No. 2 | No. 3 | No. 4 | No. 5 |
|---|---|---|---|---|---|
| Average width of sealing | 600 | 800 | 1,000 | 1,200 | 1,500 |
| material layer [μm] | | | | | |
| Width of gap [μm] | 60 | 60 | 60 | 100 | 100 |
| Hermetic reliability | ∘ | ∘ | ∘ | ∘ | ∘ |

TABLE 2

| | No. 6 | No. 7 | No. 8 | No. 9 | No. 10 |
|---|---|---|---|---|---|
| Average width of sealing | 600 | 800 | 1,000 | 1,200 | 1,500 |
| material layer [μm] | | | | | |
| Width of gap [μm] | 0 | 0 | 0 | 0 | 0 |
| Hermetic reliability | x | x | x | x | x |

First, a glass batch was prepared by blending various raw materials, such as oxides and carbonates, so as to include as a glass composition, in terms of mol %, 39% of Bi₂O₃, 23.7% of B₂O₃, 14.1% of ZnO, 2.7% of Al₂O₃, 20% of CuO, and 0.5% of Fe₂O₃. The glass batch was loaded into a platinum crucible, and melted at 1,200° C. for 2 hours. Next, the resultant molten glass was formed into a thin sheet shape with a water-cooling roller. Finally, the bismuth-based glass in the thin sheet shape was pulverized with a ball mill, and then subjected to air classification. Thus, bismuth-based glass powder was obtained.

Further, the bismuth-based glass powder and refractory filler powder were mixed at a ratio of 70.0 vol %:30.0 vol % to produce composite powder. In this case, the bismuth-based glass powder had an average particle diameter D₅₀ of 1.0 μm and a 99% particle diameter D₉₉ of 2.5 μm, and the refractory filler powder had an average particle diameter D₅₀ of 1.0 μm and a 99% particle diameter D₉₉ of 2.5 μm. The refractory filler powder is β-eucryptite.

The obtained composite powder was measured for a thermal expansion coefficient. As a result, it was found that the thermal expansion coefficient was 71×10⁻⁷/° C. The thermal expansion coefficient is a value measured with a push-rod type TMA apparatus in a measurement temperature range of from 30° C. to 300° C.

Next, the composite powder was used to form a sealing material layer in a frame shape along a peripheral end edge of a cover glass formed of borosilicate glass (BDA manufactured by Nippon Electric Glass Co., Ltd., thickness: 0.3 mm). Specifically, first, the composite powder, a vehicle, and a solvent were kneaded so as to achieve a viscosity of about 100 Pa·s (25° C., shear rate: 4), and then further kneaded with a triple roll mill until powders were homogeneously dispersed to be formed into a paste. Thus, a composite powder paste was obtained. A vehicle obtained by dissolving an ethyl cellulose resin in tripropylene glycol monobutyl ether was used as the vehicle. After that, the composite powder paste was printed in a frame shape with a screen printing machine along the peripheral end edge of the cover glass at a position distant from the peripheral end edge of the cover glass by 100 μm. Although a gap in a linear shape was formed over the entire periphery of each of the sealing material layers according to Sample Nos. 1 to 5 along the center line thereof, no gap was formed in each of the sealing material layers according to Sample Nos. 6 to 10. Further, the composite powder paste was dried at 120° C. for 10 minutes under an air atmosphere, and then fired at 500° C. (at a temperature increase rate of 5° C./min from room temperature and at a temperature reduction rate of 5° C./min to room temperature) for 10 minutes under an air atmosphere. Thus, a sealing material layer having dimensions shown in the tables was formed on one surface of the cover glass.

Subsequently, a package base including a substantially rectangular base part and a frame part in a substantially frame shape arranged along a periphery of the base part was produced. Specifically, green sheets (MLB-26B manufactured by Nippon Electric Glass Co., Ltd.) were laminated on each other so as to obtain a package base having the same length and width dimensions as the cover glass, and further having the following dimensions: a width of the frame part of 2.5 mm; a height of the frame part of 2.5 mm; and a thickness of the base part of 1.0 mm, and were pressure bonded to each other, and then fired at 870° C. for 20 minutes. Thus, a package base formed of glass ceramic was obtained.

Finally, the package base and the cover glass were arranged so as to be laminated on each other via the sealing material layer. After that, while the cover glass was pressed with a pressing jig, a semiconductor laser having a spot diameter of from 0.8 mm to 2.3 mm and a wavelength of 808 nm was radiated at an irradiation speed of 15 mm/sec to the sealing material layer from a cover glass side to soften and deform the sealing material layer, to thereby hermetically integrate the package base and the cover glass with each other. Thus, a hermetic package was obtained. The laser irradiation diameter and output were adjusted so that the average width of the sealing material layer after the laser sealing was 120% of the average width of the sealing material layer before the laser sealing.

Next, the resultant hermetic package was evaluated for hermetic reliability. Specifically, the resultant hermetic package was subjected to a highly accelerated temperature and humidity stress test (temperature: 85° C., relative humidity: 85%, 1,000 hours), and then, the neighborhood of the sealing material layer was observed. The hermetic reliability was evaluated as follows: a case in which cracks, a breakage, and the like were not observed at all was represented by Symbol “∘”, and a case in which cracks, a breakage, and the like were observed was represented by Symbol “x”.

As apparent from Table 1, each of Sample Nos. 1 to 5, in which a gap was formed in the sealing material layer, received satisfactory evaluation in hermetic reliability. Meanwhile, as apparent from Table 2, each of Sample Nos. 6 to 10, in which no gap was formed in the sealing material layer, received poor evaluation in hermetic reliability.

### INDUSTRIAL APPLICABILITY

The hermetic package of the present invention is suitable as a hermetic package having mounted therein an internal device, such as a microelectromechanical system (MEMS) device. Other than the above, the hermetic package of the present invention is also suitably applicable to, for example, a hermetic package having housed therein a piezoelectric vibration device, a wavelength conversion device in which quantum dots are dispersed in a resin, or the like.

1. A cover glass, comprising a sealing material layer on one surface,
wherein the sealing material layer has a gap formed therein.

2. The cover glass according to claim 1, wherein a width of the gap of the sealing material layer is from 2% to 60% of an average width of the sealing material layer.

3. The cover glass according to claim 1, wherein the gap is formed along a center line of the sealing material layer.

4. The cover glass according to claim 1, wherein the sealing material layer is formed in a frame shape along a peripheral end edge of the cover glass.

5. The cover glass according to claim 1, wherein the sealing material layer has an average thickness of less than 8.0 μm.

6. A hermetic package, comprising a package base and a cover glass,
wherein the hermetic package further comprises a sealing material layer arranged between the package base and the cover glass, and
wherein the sealing material layer has a gap formed therein.

7. The hermetic package according to claim 6, wherein a width of the gap of the sealing material layer is from 2% to 60% of an average width of the sealing material layer.

8. The hermetic package according to claim 6,
wherein the package base comprises a base part and a frame part formed on the base part,
wherein the package base has an internal device housed within the frame part, and
wherein the sealing material layer is arranged between a top of the frame part of the package base and the cover glass.

9. The hermetic package according to claim 6, wherein the package base comprises any one of glass, glass ceramic, aluminum nitride, and aluminum oxide, or a composite material thereof.

10. The cover glass according to claim 2, wherein the gap is formed along a center line of the sealing material layer.

11. The hermetic package according to claim 7,
wherein the package base comprises a base part and a frame part formed on the base part,
wherein the package base has an internal device housed within the frame part, and
wherein the sealing material layer is arranged between a top of the frame part of the package base and the cover glass.
